(19) United States
(12) Patent Application Publication
(10) Pub. No.: US 2003/0205711 A1
(43) Pub. Date: Nov. 6, 2003

(54) N-type nitride semiconductor laminate and semiconductor device using same

(76) Inventors: Koji Tanizawa, Anan-shi, Tokushima (JP); Yasunobu Hosokawa, Anan-shi, Tokushima (JP)

Correspondence Address: Raj S Dave, Morrison & Foerster, Suite 300, 1650 Tysons Boulevard, McLean, VA, 22102, US

(21) Appl. No.: 10/312,848

(22) PCT Filed: Jul. 2, 2001
(86) PCT No.: PCT/JP01/05690

(30) Foreign Application Priority Data
Jul. 3, 2000 (JP) 2000-201341
Feb. 2, 2001 (JP) 2001-27070
May 24, 2001 (JP) 2001-155577

(51) Int. Cl. H01L 27/15

(52) U.S. Cl. 257/79

(57) ABSTRACT

An N-type nitride semiconductor laminate includes a substrate, a buffer layer made of AlₐGa₁₋ₐN (0.05≦a≦0.8) which is formed on a surface of the substrate, and an n-side nitride semiconductor layer which is formed on the buffer layer.

### TECHNICAL FIELD

This invention relates to an N-type gallium nitride semiconductor laminate used in the light emitting devices such as LED (light emitting diode) and LD (laser diode), solar cells, light receiving devices such as optical sensors and electronic devices such as transistors and power devices, and a semiconductor device using the same.

### BACKGROUND ART

Nitride semiconductors have been recently produced as materials used for a high bright blue LED and a pure green LED in various light sources for a full color LED display, a traffic signal and an image scanner and the like. Nitride semiconductors are expected to have a multitude of uses in the future.

Gallium nitride compound semiconductor are promising semiconductor materials, but it is difficult to fabricate bulk single crystal thereof. Then, under present circumstances, the hetero-epitaxy technology is used usually in which gallium nitride type compound semiconductors are grown on the auxiliary substrate such as a sapphire substrate or SiC substrate using metal-organic chemical vapor deposition (MOCVD). Particularly, in the case that the sapphire substrate is used, the process is used in which the buffer layer made of AlN or GaN is formed on the sapphire substrate at a low temperature of about 600° C. and then, the gallium nitride compound semiconductor is grown thereon.

However, for the gallium nitride compound semiconductor layer made using the vapor deposition, it is very difficult to control the crystal growth thereof and to achieve a stable and good crystallinity during the mass production. Therefore, when the gallium nitride compound semiconductor layer is grown on plural wafers, there are produced not a few wafers on which a lot of pits occur, that is, defective wafers.

This invention has been accomplished to solve the above-mentioned problems. The object of the present invention is to provide an N-type nitride semiconductor laminate which enables the manufacturing of devices with high yield and a semiconductor device using the same which has an excellent performance such as a static withstand voltage.

### DISCLOSURE OF INVENTION

### SUMMARY OF THE INVENTION

The N-type nitride semiconductor laminate of the present invention is characterized by comprising a substrate, a buffer layer made of AlₐGa₁₋ₐN (0.05≦a≦0.8) which is formed on the surface of the substrate and an n-side nitride semiconductor layer which is formed on the buffer layer.

The buffer layer is preferably made of AlₐGa₁₋ₐN (0.1≦a≦0.5).

The n-side nitride semiconductor layer may preferably include an undoped Al_{b}Ga_{1-b}N which is formed on the buffer layer and an n-type contact layer containing an n-type impurity which is formed on the undoped Al_{b}Ga_{1-b}N layer.

In this specification, the word “undoped” means an intentionally not doped layer. If the impurity is intentionally not doped, the layer into which the impurity is mixed due to the diffusion of the impurity from the adjacent layers or the contamination by the material or the equipment is referred to as an undoped layer. The impurity that is mixed into the layer due to the diffusion may have a gradient of concentration within the layer.

It is preferable that the n-side first multi-layered film may be formed on the n-type contact layer and may include an undoped bottom layer.

The n-side first multi-layered film may more preferably include a middle layer doped with an n-type impurity which is formed on the undoped bottom layer.

The n-side first multi-layered film may more preferably include an undoped top layer which is formed on the middle layer doped with an n-type impurity.

The n-type contact layer may preferably have a thickness larger than that of the middle layer doped with an n-type impurity which is included within the n-side first multi-layered film.

The undoped top layer may preferably have a thickness smaller than that of the undoped bottom layer in the n-side first multi-layered film.

The undoped Al_{b}Ga_{1-b}N layer may preferably be formed of Al_{b}Ga_{1-b}N (0.001≦b≦0.1).

The n-type contact layer may preferably have a thickness in a range of 6 to 20 μm.

The static withstand voltage of the device which is fabricated using the nitride semiconductor laminate of the present invention can be enhanced. Therefore, according to the present invention, there is also provided a semiconductor device comprising an n-type nitride semiconductor laminate which is formed by laminating the n-side nitride semiconductor layers and the p-side nitride semiconductor layers with the active layer interposed, wherein the buffer layer is made of AlₐGa₁₋ₐN (0.05≦a≦0.8).

If the buffer layer is made of AlₐGa₁₋ₐN (0.1≦a≦0.5), the nitride semiconductor layers can be grown with a good crystallinity.

The active layer may preferably be formed of In_{c}Ga_{1-c}N (0<c<1) and the n-side nitride semiconductor layer may preferably further comprise an n-side second multi-layered film formed on the n-side first multi-layered film by laminating a first nitride semiconductor layer formed of In_{d}Ga_{1-d}N (0<d<1, d<c) and a second nitride semiconductor layer formed of InₑGa₁₋ₑN (0≦e<1, e<d).

### BRIEF DESCRIPTION OF DRAWINGS

The above and other objectives and features of the present invention will become more apparent from the following description of preferred embodiments thereof with reference to accompanying drawings, throughout which like parts are designated by like reference numerals, and wherein:

FIG. 1 is a schematic sectional view of the nitride semiconductor device of the first embodiment according to the present invention,

FIG. 2 shows the results of the number of pits measured with varying the Al proportion of the buffer layer,

FIG. 3 shows the results of the surface roughness of the p-type contact layer measured with varying the Al proportion of the buffer layer,

FIG. 4 is a schematic sectional view of the nitride semiconductor device of the second embodiment according to the present invention,

FIG. 5 is a schematic sectional view of the laser device structure of Example 4.

### DETAILED DESCRIPTION OF THE PREFERRED EMBODIMENTS

This application is based on application Nos. 2001-155577, 2000-201341 and 2001-27070 filed in Japan, the content of which is incorporated herein by reference. Hereinafter, the nitride semiconductor device of the embodiments according to the present invention will be described with reference to the accompanying drawings.

### First Embodiment

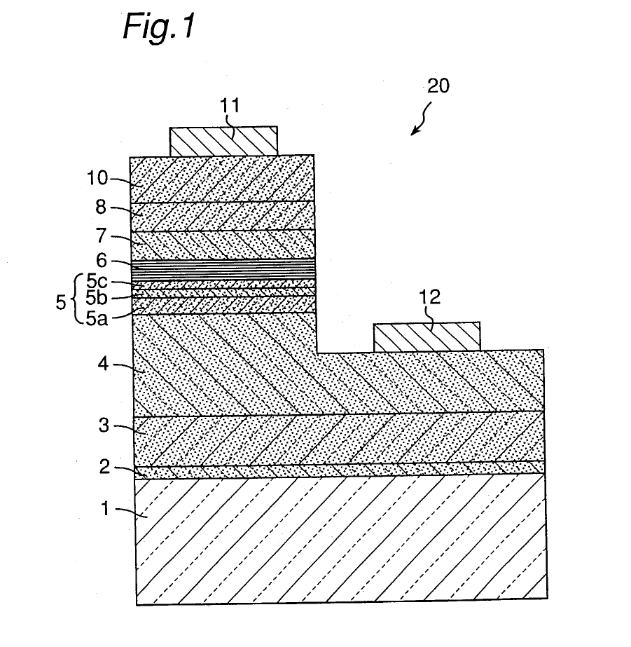

FIG. 1 is a schematic sectional view of the nitride semiconductor device of the first embodiment according to the present invention.

The nitride semiconductor device of the present invention is not limited to the device of the embodiment that will be described. Any nitride semiconductor device which comprises a buffer layer made of AlₐGa₁₋ₐN (0.05≦a≦0.8, preferably 0.1≦a≦0.5) on the surface of the substrate and nitride semiconductor layers on the buffer layer may be applied.

The nitride semiconductor device 20 of the first embodiment, as shown in FIG. 1, for example, comprises a substrate 1 having on the surface deposited successively in this order with a buffer layer 2, an undoped Al_{b}Ga_{1-b}N layer 3, an n-type contact layer 4 containing an n-type impurity, an n-side first multi-layered film 5, an n-side second multi-layered film 6, an active layer 7 of a multiple quantum-well structure, a p-type cladding layer 8 in the form of a superlattice structure, and a p-type contact layer 10 containing a p-type impurity. Further, the nitride semiconductor device 20 of the first embodiment comprises an n-electrode 12 on the n-type contact layer 4 and a p-electrode 11 on the p-type contact layer 10.

Hereinafter, each element of the nitride semiconductor device 20 according to the first embodiment will be described in details.

In the nitride semiconductor device 20, the substrate 1 may be employed in the form of a sapphire substrate having its principal surface represented by a C-, R- or A-face, an insulative substrate of, for example, spinel (MgAl₂O₄), or a semiconductor substrate made of, for example, SiC (including 6H, 4H or 3C), Si, ZnO or GaAs.

The buffer layer 2 formed on the substrate 1 is made of nitride semiconductor represented by the general formula AlₐGa₁₋ₐN (0.05≦a≦0.8), more preferably AlₐGa₁₋ₐN (0.1≦a≦0.5). The buffer 2 acts as a bottom layer on which an undoped Al_{b}Ga_{1-b}N layer having a less number of pits and other layers are formed.

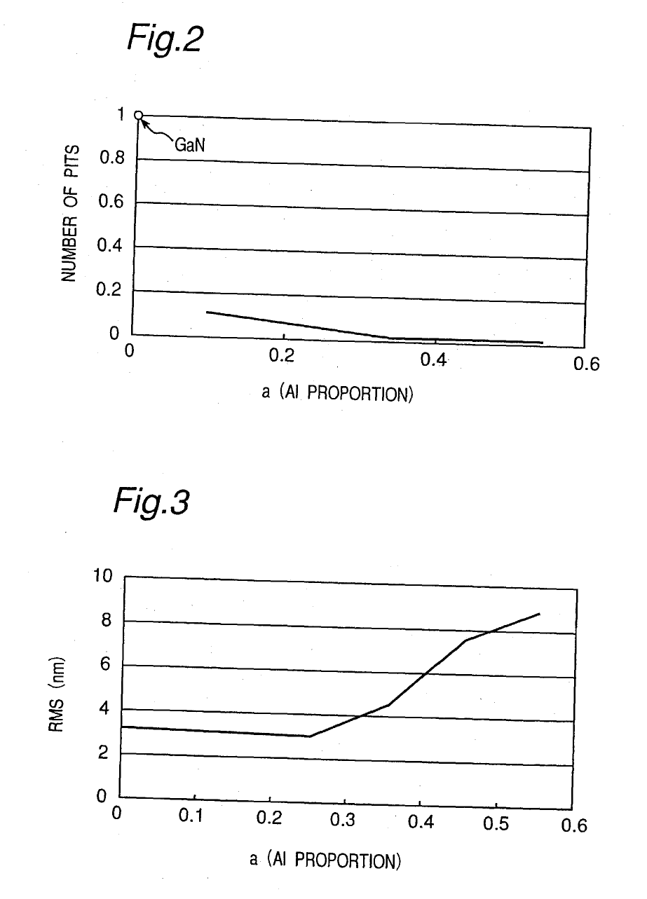

For the semiconductor device 20 comprising a buffer layer 2 made of AlₐGa₁₋ₐN, the proportion of Al, a, was varied and the number of pits per unit area on the surface of the p-type contact layer 10 (described later) was measured. FIG. 2 shows the ratio of the number of pits (standardized results) in the case that the number of pits is 1 when the proportion of Al, a, is 0 (GaN).

FIG. 2 shows that when Al is contained in the AlₐGa₁₋ₐN buffer layer 2 (a is not less than 0.05), the number of pits observed on the surface of the p-type contact layer 10 decreases remarkably.

If the layers are grown epitaxially on the crystal layer having a lot of pits, such a defect is propagated into the grown layers. As in this embodiment, the undoped Ala_{b}Ga_{1-b}N layer 3 can be formed with a good crystallinity on the buffer layer 2 containing Al (a is not less than 0.05). Moreover, it is conceivable that the contact layer 4, the n-side first multi-layered film 5, the n-side second multi-layered film 6, the active layer 7, the p-type cladding layer 8 and the p-type contact layer 10 doped with a p-type impurity can be formed with a good crystallinity, respectively.

The following Table 1 shows the results of the static withstand voltage characteristics that were evaluated using the semiconductor device (Example 2 described later) comprising a buffer layer 2 having the above-mentioned proportion of Al, a, of 0.25 and the semiconductor device (Comparative Example 2 described later) comprising a buffer layer made of GaN. Table 1 shows the ratio of the broken devices (the ratio of defective items) which have been broken when the forward static voltage and backward static voltage not more than 500 V was applied at 200 pF and 0 Ω.

TABLE 1

| | Forward static | Backward static |
|---|---|---|
| | voltage | voltage |
| Example 2 | 2.7% | 8% |
| Comparative Example 2 | 22.3% | 47.6% |

Table 1 shows that for the semiconductor device comprising a buffer layer 2 containing Al, as in this embodiment, the ratio of broken devices (the ratio of defective items) that are broken down at the forward static voltage and the backward static voltage of not more than 500 V decreases, compared with those for the semiconductor device comprising a buffer layer containing no Al. Therefore, the occurrence of the defective items can be decreased during manufacturing and handling.

FIG. 3 shows the results of the surface roughness of the p-type contact layer 10 measured with varying the Al proportion of the AlₐGa₁₋ₐN buffer layer in the semiconductor device. The semiconductor device used for the measurement was fabricated in the same way as in Example 1 described later, except that the Al proportion of the AlₐGa₁₋ₐN buffer layer was varied. The surface roughness of the p-type contact layer 10 was obtained by measuring the surface states of the region of 10 μm×10 μm of the layer 10 with an atomic force microscope (AFM) and by calculating root mean square (RMS) of the roughness.

As shown in FIG. 3, the surface roughness of the p-type contact layer 10 increases as the proportion of Al increase, compared with that in the semiconductor device comprising a buffer layer in which the proportion of Al is 0. The surface of the p-type contact layer 10 was observed with an optical microscope. There was no difference in the surface states among any semiconductor devices and there were observed no asperities in the range of the proportion of Al being 0.1 to 0.4. When the proportion of Al exceeded 0.4, a few asperities began to be observed. When the proportion of Al exceeded 0.5, the uneven surface was clearly observed.

Therefore, the proportion of Al, a, in the AlₐGa₁₋ₐN buffer layer 2 is preferably 0.05≦a≦0.8, more preferably 0.1≦a≦0.5. The buffer layer 2 having such a composition is formed on the substrate and each nitride semiconductor layer which will be described later is grown on the buffer layer 2, with the result that gallium nitride compound semiconductor layers having a small number of pits can be laminated.

If the thickness of the buffer layer 2 is controlled to be in the range of 0.002 to 0.5 μm, the nitride semiconductor can be grown on the buffer layer 2 with a good crystallinity. The thickness of the buffer layer 2 may be preferably controlled to be in the range of 0.005 to 0.2 μm, more preferably in the range of 0.01 to 0.02 μm. The growing temperature of the buffer layer 2 may be preferably controlled to be in the range of 200 to 900° C., more preferably in the range of 400 to 800° C. This is because, if the buffer layer having a good polycrystalline can be formed, a nitride semiconductor having a good crystallinity can be grown the buffer layer 2 with the polycrystalline acting as a seed crystal.

In the nitride semiconductor device 20, the undoped Al_{b}Ga_{1-b}N (0≦b<1) layer 3 means the layer grown without doping an n-type impurity. When the undoped Al_{b}Ga_{1-b}N layer 3 is grown on the buffer layer 2, the crystallinity of the undoped Al_{b}Ga_{1-b}N layer 3 is good. Moreover, the layers such as an n-side contact layer 4 which is grown on the undoped Al_{b}Ga_{1-b}N layer can have a good crystallinity. The thickness of the undoped Al_{b}Ga_{1-b}N layer is not less than 0.01 μm, preferably not less than 0.5 μm, more preferably not less than 1 μm. So long as the thickness is as specified, the n-side contact layer 4 and the layers which is to be formed thereon can be grown with a better crystallinity. Although the uppermost limit for the undoped Al_{b}Ga_{1-b}N layer 3 is not specifically limited so as to obtain the effect of the invention, the uppermost limit thereof may be controlled as appropriate in consideration of manufacturing efficiency and the like. If the uppermost limit for the undoped Al_{b}Ga_{1-b}N layer 3 is controlled to be such that the total thickness of the undoped Al_{b}Ga_{1-b}N layer 3, the n-type contact layer 4 and the n-side multi-layered film 5 is in the range of 2 to 20 μm, the static withstand voltage can be increased. In particular, where the undoped Al_{b}Ga_{1-b}N layer 3 is made of Al_{b}Ga_{1-b}N (b>0), it is more preferable that the value of b is smaller than that of Al proportion, a, of the AlₐGa₁₋ₐN buffer layer 2 (b<a) and larger than that of Al proportion, f, of the n-type contact layer 4 made of InₑAl_{f}Ga_{1-e-f}N (0≦e, 0≦f, e+f≦1) (b>f), the value of b being in the range of 0.001≦b≦0.1. Thus, the proportion of Al is decreased successively in such a laminating order of the AlₐGa₁₋ₐN buffer layer 2, the undoped Al_{b}Ga_{1-b}N layer 3 and the n-type contact layer 4, resulting in that the undoped Al_{b}Ga_{1-b}N layer 3 can also be acted as a buffer layer. Thereby, the number of pits in each nitride semiconductor layer can be decreased. Where the undoped Al_{b}Ga_{1-b}N layer 3 is made of GaN, the thickness thereof is preferably not less than 1.5 μm. On the other hand, where the undoped Al_{b}Ga_{1-b}N layer 3 contains Al (b>0), the thickness is preferably in the range of 0.1 μm to 0.5 μM. Where the thickness is small in this way, time for manufacturing devices can be shortened and the manufacturing efficiency can be enhanced.

In the nitride semiconductor device 20, the contact layer 4 including an n-type impurity includes an n-type impurity in a concentration of not less than 1×10¹⁷/cm³, preferably not less than 3×10¹⁸/cm³, and more preferably not less than 5×10¹⁸/cm³. Thus, if the n-type contact layer is doped with an n-type impurity in a large amount in this way, Vf (forward voltage) can be decreased in the case that the nitride semiconductor device 20 is a LED device and the threshold can be decreased in the case that the nitride semiconductor device 20 is a laser device. When the concentration of the impurity departs from the above-mentioned range, Vf is less prone to decrease. In the first embodiment, since the n-type contact layer 4 includes an n-type impurity in a small concentration and is formed on the undoped Al_{b}Ga_{1-b}N layer 3 having a good crystallinity, even the n-type contact layer 4 including an n-type impurity in a large concentration can be formed with a good crystallinity. Although the uppermost limit for the concentration of the n-type impurity in the n-type contact layer 4 is not specifically limited, the concentration is preferably not more than 5×10²¹/cm³ so as to hold the function as a contact layer. The concentration of the impurity can be measured using various measuring methods, such as Secondary Ion Mass Spectrometry (SIMS).

The n-type contact layer 4 is made of the material represented by the general formula InₑAl_{f}Ga_{1-e-f}N (0≦e, 0≦f, e+f≦1). The n-type contact layer is preferably made of GaN or Al_{f}Ga_{1-f}N (f is not more than 0.2) to obtain a nitride semiconductor layer having a less crystal defect. Since the n-electrode is formed on the upper surface of the n-type contact layer 4, the thickness of the n-type contact layer 4 is preferably in the range of 0.1 to 20 μm, more preferably 1 to 20 μm, so as to decrease the resistance of the n-type contact layer 4 and Vf of the light emitting device.

The uppermost limit for the thickness of the n-type contact layer 4 is preferably controlled to be in such a range that the total thickness of the undoped Al_{b}Ga_{1-b}N layer 3, the n-type contact layer 4 and the n-side first multi-layered film 5 is 2 to 20 μm. In addition to the composition of the buffer layer 2, the nitride semiconductor device 20 includes several layers that are closely related to the generation of pits. Such layers are the undoped layer 3, the n-type contact layer 4, and the n-side multi-layered film 5, all formed on the buffer layer 2, and the total thickness of these layers 3, 4, 5 affects the generation of the pits. When the buffer layer 2 is formed of AlₐGa₁₋ₐN (0.05≦a≦0.8, more preferably 0.1≦a≦0.5) and the total thickness of the layers 3, 4, 5 ranges from 2 to 20 μm, it becomes possible to effectively reduce the number of the pits that may appear in each nitride semiconductor layer. The number of the pits can be further reduced if the total thickness of the layers 3, 4, 5 ranges from 4 to 20 μm. In terms of effective radiation of heat generated within the nitride semiconductor device 20 and decrease of Vf, it is further preferred that the total thickness of the layers 3, 4, 5 be in the range of 6 to 20 μm. If the n-side first multi-layered film 5, which will be described later, has a relatively large thickness, the n-type contact layer 4 can be omitted.

The n-side first multi-layered film 5 comprises three layers including an undoped bottom layer 5a, a middle layer 5b doped with an n-type impurity and an undoped top layer 5c in this order from the substrate 1. In this embodiment, the n-side first multi-layered film may include any layers other than the bottom layer 5a to the top layer 5c. The n-side first multi-layered film 5 may be close to the active layer, or may be formed with other layers interposed between the film and the active layer. As in the first embodiment 1, the n-side first multi-layered film 5 is formed in the n-side region, with the result that the light emitting output as well as the static withstand voltage can be increased.

The bottom layer 5a to the top layer 5c may be made of nitride semiconductor having various compositions represented by In_{g}AlₕGa_{1-g-h}N (0≦g<1, 0≦h<1) and may preferably be made of GaN. The composition of each layer of the first multi-layered film 5 may be the same as or different from that in the other layer.

In this embodiment, the thickness of the n-side first multi-layered is preferably 175 to 12000 angstroms, more preferably 1000 to 10000 angstroms, most preferably 2000 to 6000 angstroms, so as to optimize Vf and enhance the static withstand voltage.

It is desirable that the thickness of the n-side first multi-layered film 5 is controlled to be in the above-mentioned range and further, the total thickness of the n-side first multi-layered film 5, the undoped GaN layer 3 and the n-type contact layer 4 is controlled to be in the above-mentioned range of 2 to 20 μm where the static withstand voltage can be enhanced.

The thickness of the n-side first multi-layered film 5 can be controlled to be in the preferable range as specified above by adjusting each thickness of the bottom layer 5a, the middle layer 5b and the top layer 5c as appropriate. Although the lowermost limit for each thickness of the bottom layer 5a, the middle layer 5b and the top layer 5c comprising the n-side first multi-layered film 5 is not specifically limited, the thickness is controlled as follows. Since the degree of the influence which is exerted on the various performances of the device varies with the position of the bottom layer 5a, the middle layer 5b and the top layer 5c in the n-side first multi-layered film, the characteristics of each layer involved in the device performance must be particularly considered. Therefore, the thickness of any two layers is fixed and the thickness of the other layer is varied stepwise to measure the range of the thickness where the characteristics of the device are good and each layer of the n-side first multi-layered film 5 is adjusted to each other.

In some cases, each layer included in the n-side first multi-layered film 5 does not influence directly on the static withstand voltage on a standalone basis, but each layer is combined into the n-side first multi-layered film 5, resulting in enhancing various device characteristics as a whole. Especially, each layer is combined into the n-side first multi-layered film to enhance drastically the light emitting output and the static withstand voltage. Such an effect can be obtained only after each layer of the n-side multi-layered film 5 is laminated and the device is fabricated. The thickness of each layer will be described concretely in the following part. The trend of the device characteristics varying with the thickness will be summarized.

The thickness of the undoped bottom layer 5a is 100 to 10000 angstroms, preferably 500 to 8000 angstroms, and more preferably 1000 to 5000 angstroms. The static withstand voltage increase as the thickness of the undoped bottom layer 5a increases gradually. Vf rises suddenly around 10000 angstroms. On the other hand, Vf decreases as the thickness decreases, but the static withstand voltage decrease largely. When the thickness is less than 100 angstroms, the yield tends to decrease as the static withstand voltage decrease. Since it is conceivable that the bottom layer 5a has the function of improving the influence of the decrease in crystallinity of the n-side contact layer 4 containing an n-type impurity, the bottom layer 5a preferably has a thickness of about 500 to about 8000 angstroms from the view point of allowing such a function to be performed effectively.

The thickness of the middle layer 5b is preferably smaller than that of the n-type contact layer 4 and is 50 to 1000 angstroms, preferably 100 to 500 angstroms, more preferably 150 to 400 angstroms. The middle layer 5b doped with an n-type impurity has the function of increasing the carrier concentration and enhancing relatively the light emitting output. The light emitting device without the middle layer has a light emitting output lower than that of the device with the middle layer.

Conversely, if the thickness of the middle layer 5b doped with an n-type impurity exceeds 1000 angstroms, the light emitting output decreases. From the view point of only the static withstand voltage, if the thickness of the middle layer 5b is large, the static withstand voltage can be enhanced. To the contrary, if the thickness of the middle layer is less than 50 angstroms, the static withstand voltage is smaller than that in the case that the thickness is not less than 50 angstroms.

The thickness of the undoped top layer 5c is preferably smaller than that of the undoped bottom layer 5a and is 25 to 1000 angstroms, preferably 25 to 500 angstroms and more preferably 25 to 150 angstroms. The undoped top layer 5c is formed adjacent to the active layer, within the n-side first multi-layered film 5, or formed closest to the active layer, to prevent the leakage current. The top layer 5c having a thickness of less than 25 angstroms cannot prevent the increase of the leakage current effectively. If the thickness of the top layer 5c exceeds 1000 angstroms, Vf increases and the static withstand voltage decreases.

Thus, it is noted that the device characteristics are liable to be influenced by the variation of each thickness of the bottom layer 5a to the top layer 5c. Each thickness of the bottom layer 5a to the top layer 5c is controlled in such a manner that the balance among various device characteristics is improved and particularly, the light emitting output and the static withstand voltage are improved when the bottom layer 5a, the middle layer 5b and the top layer 5c are combined.

The composition of each layer comprising the first multi-layered film 5 can be that represented by In_{g}AlₕGa_{1-g-h}N (0≦g<1, 0≦h<1). The composition of one layer may be the same as or different from that of the other layers. However, each layer comprising the first multi-layered film 5 may be preferably made of the material having a composition containing a small proportion of In and Al, more preferably made of GaN or AlₕGa₁₋ₕN, most preferably made of GaN to improve the crystallinity and decrease Vf. When the n-side first multi-layered film 5 is made of AlₕGa₁₋ₕN, h can be controlled to be in the range of 0≦h<1 as appropriate. It is preferable that the proportion of Al is reduced to improve the crystallinity and decrease Vf.

The amount of the n-type impurity doped into the middle layer 5b of the first multi-layered film 5 is preferably not less than 3×10¹⁸/cm³ and more preferably not less than 5×10¹⁸/cm³. The uppermost limit for the amount of the n-type impurity doped into the middle layer 5b of the first multi-layered film 5 is desirably 5×10²¹/cm³. So long as the doped amount is not more than the specified uppermost limit, the middle layer 5b having a relatively good crystallinity can be formed and Vf can be reduced without the decrease of the light emitting output. An n-type impurity includes Group IVB and VIB elements such as Si, Ge, Se, S, O and the like and Si, Ge and S are preferred. In the case that the active layer is formed on the first multi-layered film 5, the top layer 5c, which is adjacent to the active layer, of the first multi-layered film 5 is made of, for example, GaN, in order that the top layer 5c can act as a barrier layer to the active layer. That is, the bottom layer 5a and the top layer 5c, which are adjacent to other layers, of the n-side first multi-layered film 5 not only acts as a part of the n-side first multi-layered film 5, but also acts another role in relation to the adjacent layer. In this embodiment, in place of the n-side first multi-layered film 5, a single undoped layer of not a multi-layered structure may be formed. The single undoped layer may be made of nitride semiconductor represented by the general formula of In_{g}AlₕGa_{1-g-h}N (0≦g<1, 0≦h<1) and preferably made of nitride semiconductor having a small proportion of In and Al, more preferably of GaN or AlₕGa_{1-g-h}N from the viewpoint of crystallinity and the reduced Vf, most preferably of GaN. In the case that the single undoped layer is made of AlₕGa_{1-g-h}N, h can be controlled to be in the range of 0≦h<1 as appropriate and the nitride semiconductor wherein the proportion of Al is small is preferred since the smaller the Al proportion, the better the crystallinity and Vf. Thus, the device wherein the single undoped layer is formed shows a static withstand voltage a little lower than that of the device wherein the n-side multi-layered film 5 is formed but higher than that of the conventional device. The device comprising the single undoped layer can have characteristics other than the static withstand voltage which are almost the same to those of the device comprising the n-side multi-layered film 5. The thickness of the single undoped layer is preferably 1000 to 3000 angstroms to realize better device characteristics, although not exclusively limited thereto.

In this embodiment, the n-side second multi-layered film 6 is formed by laminating a first nitride semiconductor layer containing In and a second nitride semiconductor layer of a different composition from the first nitride semiconductor layer. The number of the first and second nitride semiconductor layers may be one or more with the minimum total number of those layers being three or preferably four or more.

In the n-side second multi-layered film 6, the thickness of at least one of the first and second nitride semiconductor layers is not more than 100 angstroms, preferably not more than 70 angstroms, more preferably not more than 50 angstroms. In the n-side second multi-layered film 6, it is more preferable that the thickness of both layers is not more than 100 angstroms, preferably not more than 70 angstroms and more preferably not more than 50 angstroms. Thus, the thickness is small ant hence the n-side second multi-layered film 6 is in the form of a super lattice structure and, therefore, the multi-layered film can have an excellent crystallinity enough to increase the output capability of the device.

For example, where one of the first and second nitride semiconductor layers has a thickness of not more than 100 angstroms and the other layer has a larger thickness larger, the thin layer of not more than 100 angstroms can have a film thickness smaller than the elastic strain limit and hence a good crystallinity, with the result that the other thick layer which is formed on the thin layer can have a good crystallinity. Therefore, the multi-layered film as a whole can have an excellent crystallinity enough to increase the output capability of the device.

Where the thickness of both first and second nitride semiconductor layers is not more than 100 angstroms, both of the first and second nitride semiconductor layer can have a thickness smaller than the elastic strain limit and therefore, the nitride semiconductor having a better crystallinity can be grown, compared with the case that both the first and second nitride semiconductor layers have a large thickness and the case that one of the first and second nitride semiconductor layers has a thickness of not more than 100 angstroms. Where both the first and second nitride semiconductor layers have a thickness of not more than 70 angstroms, the n-side second multi-layered film 6 is in the form of the super lattice structure and therefore, the n-side second multi-layered film 6 can have more excellent crystallinity. When the active layer is formed on such an n-side second multi-layered film 6, the n-side second multi-layered film 6 acts as like a buffer layer and therefore, the active layer can have an excellent crystallinity.

The n-side second multi-layered film 6 may be formed far from the active layer 7 and most preferably formed in direct contact with the active layer 7. This is because the output capability of the light emitting device wherein the n-side second multi-layered film is formed in contact active layer can be increased. As shown in FIG. 1, where the n-side second multi-layered film 6 is formed in contact with the active layer 7, one of the nitride semiconductor layers which is held in contact with an initial layer component (a well or a barrier) of the active layer 7 may be either the first nitride semiconductor layer or the second nitride semiconductor layer and thus, the sequence of lamination of the nitride semiconductor layers in the n-side second multi-layered film 6 may be arbitrarily chosen. Also, although in FIG. 1 the n-side second multi-layered film 6 is formed in direct contact with the active layer 7, a layer made of an n-type nitride semiconductor may intervene between the n-side second multi-layered film 6 and the active layer 7. The layer made of an n-type nitride semiconductor formed between the n-side second multi-layered film 6 and the active layer 7 is preferably made of GaN. Thereby, the static withstand voltage can be enhanced and the output capability of the device can be increased.

In the n-side second multi-layered film 6, the first nitride semiconductor layer is made of a nitride semiconductor containing In, preferably a ternary mixed crystal which is expressed by the following formula: InₖGa₁₋ₖN (0<k<1) wherein x is preferably not greater than 0.5 and more preferably in the range of 0.1 to 0.2. This is because too large k deteriorates the static withstand voltage and too small k increases Vf. On the other hand, the second nitride semiconductor layer may be made of any suitable nitride semiconductor, provided that the latter is different from that used for the first nitride semiconductor layer. In order, however, for the second nitride semiconductor layer of an excellent crystallinity to be grown, a nitride semiconductor InₘGa₁₋ₘN (0≦m<1, m<k) of a binary or ternary mixed crystals having a band gap energy higher than the first nitride semiconductor layer may be preferably grown, although not exclusively limited. More preferably, GaN is grown. The proportion in the first and second nitride semiconductor layers included in the n-side second multi-layered film 6 is preferably smaller than that in the active layer 7 as described later. Where the n-side second multi-layered film 6 having such a composition is formed between the buffer layer 2 and the active layer 7, the number of pits occurring in each nitride semiconductor layer can be decreased and the surface morphology can be improved to relax inner strain. “The composition is different” means, for example, that the elements constituting the nitride semiconductor (for example, the kind of the element of the binary or ternary mixed crystal), the proportion of the element, or the band gap energy and the like are different. If GaN is chosen as a material for the second nitride semiconductor layer, the multi-layered film having an excellent crystallinity can be formed. For example, the use of InₖGa₁₋ₖN (0<k<1) for the first nitride semiconductor layer and InₘGa₁₋ₘN (0≦m<1, m<k), preferably GaN for the second nitride semiconductor layer is a preferred combination of materials. The use of InₖGa₁₋ₖN, wherein k is not greater than 0.5, for the first nitride semiconductor layer and GaN for the second nitride semiconductor layer is a more preferred combination of materials.

One or both of the first and second nitride semiconductor layers may be either undoped or doped with n-type impurities (The former case is called “modulation doping”). To enhance the crystallinity, both of the first and second nitride semiconductor layers are preferably undoped, but may be modulation doped, or both the first and second nitride semiconductor layers may be doped with the n-type impurities. Where both the first and second nitride semiconductor layers are doped with the n-type impurities, the concentration of the n-type impurity in the first nitride semiconductor layer may be different from that in the second nitride semiconductor layer.

The state that either of the first and second nitride semiconductor layers is doped with an n-type impurity is called “modulation doping”. The output capability of the device can be enhanced using such a modulation doping.

The n-type impurity may be selected from the group consisting of Group IV and VI elements such as Si, Ge, Sn, S and the like and are preferably Si or Sn. Where the n-type impurity is doped, the concentration of the impurity is controlled to be not more than 5×10²¹/cm³, preferably not more than 1×10²⁰/cm³. If the concentration of the impurity exceeds 5×10²¹/cm³, the crystallinity of the nitride semiconductor layer will be deteriorated accompanied by reduction in output. A similar description equally applies to the modulation doping used for the multi-layered film as a whole.

The active layer 7 of the multiple quantum-well structure is made of a nitride semiconductor containing In and Ga, preferably InₐGa₁₋ₐN (0≦a<1). The active layer is preferably undoped (with no impurity added), although it may be doped with n-type or p-type impurities, so that a strong band-to-band light emission can be obtained with the half peak width narrowed. The active layer 7 may be doped with either or both of the n-type impurities or the p-type impurities. Where the active layer 7 is doped with the n-type impurities, the band-to-band light emission strength can further be increased as compared with the undoped active layer 7. On the other hand, where the active layer 7 is doped with the p-type impurities, it is possible to shift the peak wavelength towards an energy level about 0.5 eV lower than the peak wavelength of the band-to-band light emission, but the half peak width will increase. Where the active layer is doped with both of the n-type and p-type impurities, the light emission strength of the active layer doped only with the p-type impurities can further be increased. In particular, where the active layer doped with a p-type dopant is formed, the active layer preferably has an n-type conductivity by doping an n-type dopant such as, for example, Si therein. In order to grow the active layer having a good crystallinity, the active layer is preferably doped with no impurities, that is, undoped.

In the first embodiment, where the active layer is formed in the single quantum-well structure, the light emitting output is a little lower but the static withstand voltage is almost the same, as compared with the active layer in the multiple quantum-well structure.

The barrier and well layers forming the active layer 7 in the multiple quantum-well structure will be described in the following part. The barrier layer is made of, for example, GaN and the well layer is made of, for example, undoped In_{0.35}Ga_{0.65}N. The active layer 7 may start with the well layer and terminate with the well layer, or start with the well layer and terminate with the barrier layer. Alternatively, the active layer 7 may start with the barrier layer and terminate with the barrier layer or start with the barrier layer and terminate with the well layer. The well layer has a thickness adjusted to be not greater than 100 angstroms, preferably not greater than 70 angstroms and more preferably not greater than 50 angstroms. Although not specifically limited, the lowermost limit for the thickness of the well layer may correspond to the thickness of a single atom layer and, preferably not smaller than 10 angstroms. If the well layer is greater than 100 angstroms, the output will be difficult to decrease. The first well layer of plural well layers, that is, the well layer in the closest vicinity to the n-side second multi-layered film 6 is a Si doped layer and the other well layers are undoped layers, resulting in the decrease of Vf. The amount of Si doped is not more than 5×10²¹/cm³, preferably not more than 1×10²⁰/cm³.

On the other hand, the barrier layer has a thickness adjusted to be not greater than 2000 angstroms, preferably not greater than 500 angstroms and more preferably not greater than 300 angstroms. Although not specifically limited, the lowermost limit for the thickness of the barrier layer may correspond to the thickness of a single atom layer and, preferably not smaller than 10 angstroms. If the thickness of the barrier layer falls within the above specified range, the output can be increased. The total thickness of the active layer 7 can be determined from the viewpoint of the desirable wavelength of the device such as a LED device and the like and by adjusting the sequence of lamination and the number of barrier and well layers, although not exclusively limited thereto. Where the n-side second multi-layered film 6 is formed in contact with the active layer 7, the nitride semiconductor layer which constitutes the multi-layered film 6 and is in contact with the active layer 7 may be used as the first layer (a well layer or a barrier layer) of the active layer. Where the n-side first multi-layered film is formed in contact with the active layer 7 without forming the n-side second multi-layered film 6, the top layer 5c of the n-side first multi-layered film 6 may be use as the first layer (a well layer or a barrier layer) of the active layer 7.

The p-type cladding layer 8 doped with a p-type impurity is formed on the active layer 7. The p-type cladding layer 8 may be in the form of a multi-layered structure (super lattice structure) or a single layer structure. First, the p-type cladding layer 8 of a multi-layered structure (super lattice structure), which is a p-type multi-layered film, will be described in the following part. Hereinafter, the p-type cladding layer of a multi-layered film is referred to as a multi-layered p-type cladding layer.

The multi-layered p-type cladding layer may be formed by laminating the third nitride semiconductor layer containing Al and the fourth nitride semiconductor layer of a composition different from the third nitride semiconductor layer, wherein at least one of the third and fourth nitride semiconductor layers is doped with a p-type impurity.

The third nitride semiconductor layer is preferably made of a nitride semiconductor containing Al, more preferably AlₙGa₁₋ₙN (0<n≦1). The fourth nitride semiconductor layer is preferably made of a nitride semiconductor of binary mixed crystal or ternary mixed crystal such as AlₚGa₁₋ₚN (0≦p<1, n>p) and InᵣGa₁₋ᵣN (0≦r≦1). Where the p-type cladding layer 8 is in the form of the multi-layered film comprising the third and fourth nitride semiconductor layer as described above, the proportion of Al of the p-type multi-layered film means an average value. The third nitride semiconductor layer may be made of a nitride semiconductor containing no Al, GaN. In such a case, the crystallinity can be enhanced and the manufacturing equipment can be simplified.

Where the p-type cladding layer 8 is in the form of a super lattice structure, the crystallinity of the p-type cladding layer 8 is improved, the resistivity can be lowered, accompanied by reduction in Vf. The p-type impurity doped into the p-type cladding layer 8 may be selected from the group consisting of IIA and IIB group elements such as Mg, Zn, Ca and Be and preferably, Mg or Ca are selected.

Next, the case that the p-type cladding layer 8 doped with a p-type impurity is a single layer made of AlₜGa₁₋ₜN (0≦t≦1) will be described in the following part. Hereinafter, the p-type cladding layer of a single film is referred to as a single film p-type cladding layer.

The single film p-type cladding layer 8 is a nitride semiconductor layer made of AlₜGa₁₋ₜN (0≦t≦1) as described above. Where the single film p-type cladding layer contains no Al, the output is decreased a little, but the static withstand voltage is almost the same as compared with the single film p-type cladding layer containing Al.

The p-type contact layer 10 doped with a p-type impurity is formed on the cladding layer 8. The contact layer 10 may be made of a nitride semiconductor represented by the general formula InᵣAlₛGa₁₋ᵣ₋ₛN (0≦r, 0≦s<1, r+s<1), but may preferably be made of a nitride semiconductor of ternary mixed crystal, more preferably a nitride semiconductor of binary mixed crystal containing no In or Al, GaN, to form the p-type contact layer having an excellent crystallinity. Further, where the p-type contact layer 10 is made of binary mixed crystal containing no In or Al, a better ohmic contact with the p-type electrode 11 can be achieved and the light emitting efficiency can be enhanced.

The p-type impurity in the p-type contact layer 10 includes various p-type impurities which are used in the p-type cladding layer 8 and Mg is preferred. If Mg is used as a p-type impurity doped into the p-type contact layer 10, the p-type characteristics can be easily obtained and the ohmic contact between the p-type contact layer and the other layer can be easily formed.

The n-electrode 12 is formed on the n-side contact layer 4 and the p-electrode 11 is formed on the p-side contact layer 10 doped with a p-type impurity. Although the materials for the n- and p-electrodes are not specified for the purpose of the invention, W/Al and the like can be used for the n-electrode and Ni/Au and the like for the p-electrode.

As described above, according to the first embodiment, the semiconductor device having a good crystallinity can be fabricated with high yields.

### Second Embodiment

The second embodiment of the invention will be described in the following part. In the second embodiment, the member having the function substantially similar to that in the first embodiment is designated by like reference numeral and a detail-explanation about the member will be omitted.

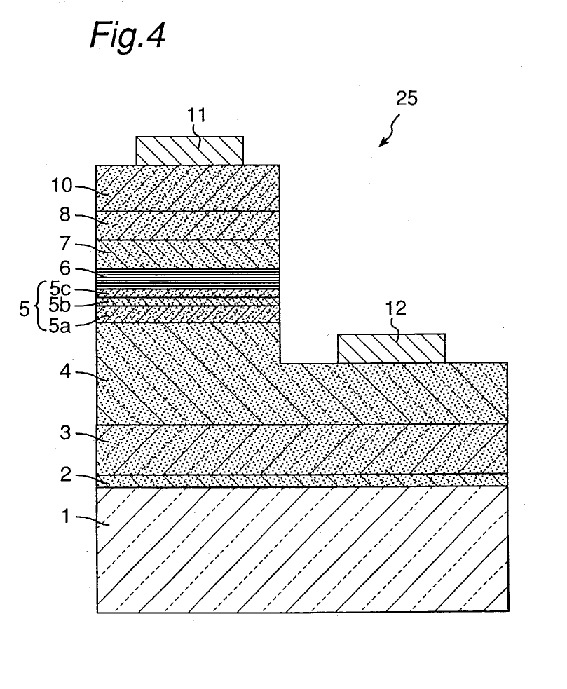

Unlike the nitride semiconductor device 20, the nitride semiconductor device 25 of the second embodiment as shown in FIG. 4 comprises another p-type lowly doped layer 9 doper with a p-type impurity in the low concentration between the p-type cladding layer 8 and the p-type contact layer 10. Where the p-type lowly doped layer 9 is formed between the p-type cladding layer 8 and the p-type contact layer 10 as in the nitride semiconductor device 25, a higher static withstand voltage can be achieved. The p-type lowly doped layer 9 will be described in the following part.

The p-type lowly doped layer 9 which is doped with a p-type impurity in a small concentration and is formed on the p-type cladding layer 8 may be made of any suitable nitride semiconductor expressed by the general formula of InᵣAlₛGa₁₋ᵣ₋ₛN (0≦r<1, 0≦s<1, r+s<1), preferably made of a nitride semiconductor of ternary mixed crystal express by InᵣGa₁₋ᵣN (0≦r<1) or AlₛGa₁₋ₛN (0≦s<1), or made of a nitride semiconductor of a binary mixed crystal of GaN to improve the crystallinity. Where the p-type lowly doped layer 9 is made of GaN, the crystallinity of the layer 9 can be improved and the output can be enhanced, resulting in the higher static withstand voltage.

The concentration of the p-type impurity in the p-type lowly doped layer 9 may be controlled to be lower than that of the p-type impurity in the p-type cladding layer 8 and the p-type contact layer 10 and may be undoped. Also, the p-type lowly doped layer 9 may be in the form of the multi-layered film. The p-type cladding layer 8 is preferably in the form of a multi-layered film or a single film containing a p-type impurity in such a concentration that the concentration is a middle one between those of the p-type lowly doped layer 9 and the p-type contact layer (moderately doped). The concentration of the impurity in the p-type contact layer 10 is preferably controlled to be higher than that of the p-type cladding layer 8 and the lowly doped layer 9.

As described above, where the p-type lowly doped layer 9 doped with a p-type impurity in a concentration lower than that of the p-type contact layer 10 and the p-type cladding layer 8 is formed between the p-type contact layer and the p-type cladding layer 8, the light emitting output can be enhanced and the static withstand voltage can be improved. According to the second embodiment, the semiconductor device having a good crystallinity can be fabricated with high yields as in the case of the first embodiment.

Various examples of the present invention will be described in the following part, although the invention is not intended to be limited thereto.

### EXAMPLE 1

Table 2 shows a laminated structure of the LED device of Example 1.

TABLE 2

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 2.25 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 200 Å/In_{0.4}Ga_{0.6}N, |
| | thickness: 30 Å) × 4 + GaN, |
| | thickness: 200 Å |
| | Total thickness: 1120 Å |
| p-type multi-layered | (Mg doped Al_{0.2}Ga_{0.8}N, thickness: 40 |
| cladding layer 8 | Å/Mg doped In_{0.03}Ga_{0.97}N, thickness: |
| | 25 Å) × 5 + Mg doped Al_{0.2}Ga_{0.8}N, |
| | thickness: 40 Å |
| | Total thickness: 365 Å |
| p-type GaN contact | Mg doped GaN, thickness: 1200 Å |
| layer 10 | |

The method of manufacturing the LED device of Example 1 will be described in conjunction with FIG. 1. First, a C-plane sapphire substrate 1 is set in the MOVPE reactor and the temperature of the substrate is increased to 1050° C. with hydrogen being flown in order to clean the substrate.

(Buffer Layer 2)

Subsequently, the temperature is decreased to 510° C. A buffer layer 2 made of Al_{0.25}Ga_{0.75}N having a thickness of about 100 angstroms is grown on the substrate 1 using hydrogen as a carrier gas, and ammonia, TMG (trimethylgallium) and TMA (trimethylaluminum) as a source of Al_{0.25}Ga_{0.75}N.

(Undoped GaN Layer 3)

After growing the buffer layer 2, only TMG is stopped and the temperature is increased to 1050° C. At 1050° C., in the same way using TMG and ammonia as a source of GaN, an undoped GaN layer 3 is grown to the thickness of 1.5μ.

Subsequently, at 1050° C., using TMG and ammonia as a source gas and silane gas as an impurity gas, an n-type contact layer 4 made of GaN doped with Si to 4.5×10¹⁸/cm³ is grown to the thickness of 2.25 μm.

(n-Side First Multi-Layered Film 5)

Next, only silane gas is stopped and at 1050° C., using TMG and ammonia gas, a bottom layer 5a made of undoped GaN is grown to the thickness of 3000 angstroms. Subsequently, at the same temperature, the silane gas is added and a middle layer 5b made of GaN doped with Si to 4.5×10¹⁸/cm³ is grown to the thickness of 300 angstroms. Further, only silane gas is stopped and at the same temperature, a top layer 5c made of undoped GaN is grown to the thickness of 50 angstroms. Thus, the first multi-layered film 5 comprising three layers, which has a total thickness of 3350 angstroms, is formed.

(n-Side Second Multi-Layered Film 6)

Next, at the similar temperature, a second nitride semiconductor layer made of undoped GaN is grown to the thickness of 40 angstroms. Next, at 800° C., using TMG, TMI and ammonia, a first nitride semiconductor layer made of undoped In_{0.13}Ga_{0.87}N is grown to the thickness of 20 angstroms. This process is repeated. The second nitride semiconductor layer and the first nitride semiconductor layer are laminated alternately in the order of the second nitride semiconductor layer+the first nitride semiconductor layer in ten layers each. Finally, the second nitride semiconductor layer made of GaN is grown to the thickness of 40 angstroms. Thus, the n-side multi-layered film 6 in the form of a super lattice structure is grown to the total thickness of 640 angstroms. “(GaN, thickness: 40 angstroms/In_{0.13}Ga_{0.87}N, thickness: 20 angstroms)×10+GaN, thickness: 40 angstroms” in the n-side second multi-layered film 6 in Table 2 means that, as described above, the second nitride semiconductor layer made of undoped GaN and the first nitride semiconductor layer made of undoped In_{0.13}Ga_{0.87}N are laminated alternately in this order in 10 layers each and finally, the second nitride semiconductor layer made of GaN is formed.

(Active Layer 7)

Next, the barrier layer made of undoped GaN is grown to the thickness of 200 angstroms. Subsequently, the temperature is decreased to 800° C. and using TMG, TMI and ammonia, the well layer made of undoped In_{0.4}Ga_{0.6}N is grown to the thickness of 30 angstroms. Five barrier layers and four well layers are laminated alternately in the order of the barrier layer+the well layer+the barrier layer+the well layer . . . +the barrier layer, resulting in the active layer 7 in the form of a multiple quantum-well structure having a total thickness of 1120 angstroms. The active layer 7 as well as the n-side second multi-layered film 6 that is laminated under the active layer are formed by laminating the GaN layer and the InGaN layer. However, the active layer 7 and the n-side second multi-layered film 6 can be distinguished by the mixed proportion of In, since the InGaN layer comprising the active layer 7 is made of In_{0.4}Ga_{0.6}N and the InGaN layer comprising the n-side second multi-layered film 6 is made of In_{0.13}Ga_{0.87}N.

(p-Type Multi-Layered Cladding Layer 8)

Next, the temperature is increased to 1050° C. and using TMG, TMA, ammonia and Cp₂Mg (cyclopentadienyl magnesium), a third nitride semiconductor layer made of p-type Al_{0.2}Ga_{0.8}N doped with Mg to 1×10²⁰/cm³ is grown to the thickness of 40 angstroms. Subsequently, the temperature is decreased to 800° C. and using TMG, TMI, ammonia and Cp₂Mg, a fourth nitride semiconductor layer made of In_{0.03}Ga_{0.98}N doped with Mg to 1×10²⁰/cm³ is grown to the thickness of 25 angstroms. These processes are repeated. The third nitride semiconductor layer and the fourth nitride semiconductor layer are laminated alternately in this order, in 5 layers each and finally, the third nitride semiconductor layer is grown to the thickness of 40 angstroms, resulting in the p-type multi-layered cladding layer in the form of a super lattice structure having a total thickness of 365 angstroms.

(p-Type GaN Contact Layer 10)

Subsequently, at 1050° C., using TMG, ammonia and Cp₂Mg, a p-type contact layer 10 made of p-type GaN doped with Mg to 1×10²⁰/cm³ is grown to the thickness of 1200 angstroms.

After the reaction is completed, the temperature is decreased to room temperature. Additionally, annealing is performed to the wafer at 700° C. in nitrogen atmosphere within the reactor, so as to make the p-type layers less resistive.

After annealing, the wafer is removed out of the reactor. A mask of a predetermined shape is formed on the surface of the uppermost p-side contact layer. And etching is conducted from the p-side contact layer side with RIE (reactive ion etching) apparatus, to expose the surface of the n-type contact layer 4, as shown in FIG. 1.

After etching, a translucent p-electrode 11 containing Ni and Au and having a thickness of 200 angstroms is formed on the almost entire surface of the uppermost p-type contact layer 10 and a p-pad electrode made of Au for bonding and having a thickness of 0.5 μm is formed on the p-electrode 11. Meanwhile, an n-electrode 12 containing W and Al is formed on the surface of the n-type contact layer 4 which has been exposed by etching. Thus, the LED device is fabricated.

For this LED device, pure green light emission of 520 nm is obtained and Vf is 3.5 V. According to the method for manufacturing semiconductor devices of Example 1, the occurrence of the LED device having a low static withstand voltage which is considered to be attributed to the occurrence of pits can be decreased extensively as compared with Comparative Example 1. Therefore, the occurrence of the defective items can be decreased. Moreover, the variation in the device characteristics due to the deterioration of the crystallinity, which is a problem in the comparative Example 1, can be reduced. Thus, the LED device can be fabricated without no device-to-device variation.

### EXAMPLE 2

Table 3 shows a laminated structure of the LED device of Example 2.

TABLE 3

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first | GaN, thickness: 3000 Å/ |
| multi-layered film 5 | Si doped GaN, thickness: 300 Å/ |
| | GaN, thickness: 50 Å |
| | Total thickness: 3350 Å |
| n-side second | (GaN, thickness: 40 Å/ |
| multi-layered film 6 | In_{0.13}Ga_{0.87}N; thickness: 20 Å) × 10 + |
| | GaN, thickness: 40 Å |
| | Total thickness: 640 Å |
| Active layer 7 | (GaN, thickness: 200 Å/In_{0.4}Ga_{0.6}N, |
| | thickness: 30 Å) × 4 + GaN, |
| | thickness: 200 Å |
| | Total thickness: 1120 Å |
| p-type multi-layered | (Mg doped Al_{0.2.0}Ga_{0.8}N, thickness: 40 |
| cladding layer 8 | Å/Mg doped In_{0.03}Ga_{0.97}N, thickness: |
| | 25 Å) × 5 + Mg doped Al_{0.2}Ga_{0.8}N, |
| | thickness: 40 Å |
| | Total thickness: 365 Å |
| Second contact layer 9 | Al_{0.05}Ga_{0.95}N, thickness: 2000 Å |
| p-type GaN contact | Mg doped GaN, thickness: 1200 Å |
| layer 10 | |

The LED device is fabricated in the same manner as in Example 1 except that the thickness of the n-type contact layer 4 is 4.165 μm and the second contact layer 9 made of undoped Al_{0.05}Ga_{0.95}N having a thickness of 2000 angstroms is formed between the p-type contact layer 10 and the p-type multi-layered cladding layer 8. The static withstand voltage obtain in Example 2 was better than that that in Example 1.

### EXAMPLE 3

Table 4 shows a laminated structure of the LED device of Example 3.

TABLE 4

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 2.25 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/In_{0.3}Ga_{0.7}N, |
| | thickness: 30 Å) × 6 + GaN, |
| | thickness: 250 Å |
| | Total thickness: 1930 Å |
| p-type multi-layered | (Mg doped Al_{0.2}Ga_{0.8}N, thickness: 40 |
| cladding layer 8 | Å/Mg doped In_{0.03}Ga_{0.97}N, thickness: |
| | 25 Å) × 5 + Mg doped Al_{0.2}Ga_{0.8}N, |
| | thickness: 40 Å |
| | Total thickness: 365 Å |
| p-type GaN contact | Mg doped GaN, thickness: 1200 Å |
| layer 10 | |

The LED device is fabricated in the same manner as in Example 1 except that the active layer is formed in the following way.

The barrier layer made of undoped GaN is grown to the thickness of 250 angstroms. Subsequently, at 800° C., using TMG, TMI and ammonia, the well layer made of an undoped In_{0.3}Ga_{0.7}N is grown to the thickness of 30 angstroms. Thus seven barrier layer s and six well layers are laminated alternately in the order of the barrier layer+the well layer+the barrier layer+the well layer . . . +the barrier layer. layer having a thickness of 75 μm is grown, resulting in active layer 7 in the form of a super lattice structure having a total thickness of 1930 angstroms.

For the resulting LED device, pure green light emission of 470 nm was obtained at a forward current of 20 mA and good results similar to those in Example 1 were obtained.

The LED in the form of a super lattice structure Of Example 3 had almost similar properties to those of Example 1.

### EXAMPLE 4

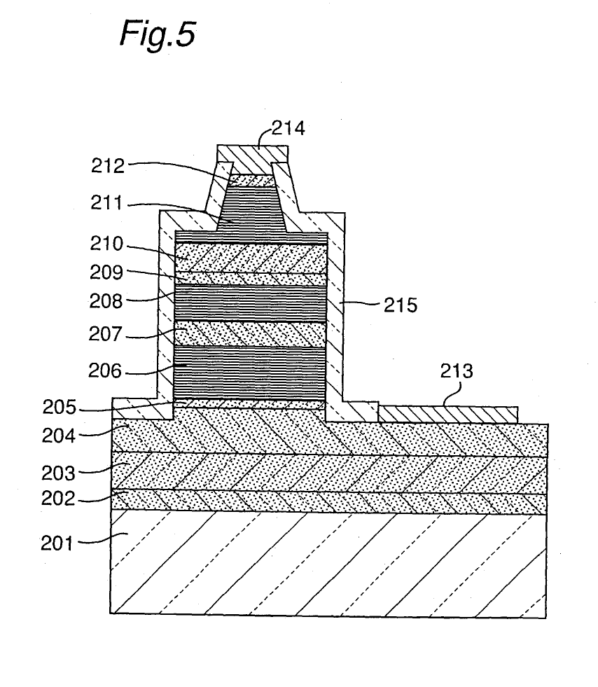

FIG. 5 is a schematic sectional view of the laser device structure of Example 4. The laser device of Example 4 will be described in the following part, with reference to FIG. 5.

The laser device having the following configuration in the same manner as in Example 1 by forming (1) a Al_{0.25}Ga_{0.75}N buffer layer 202 and an undoped GaN layer 20 on the substrate 201. Each element is as follows:

(2) n-type GaN contact layer 204 having a thickness of 3 μm

(3) n-side multi-layered film 205 similar to that in Example 1

(4) n-type Al_{0.14}Ga_{0.86}N/GaN cladding layer 206 in the super lattice structure having a thickness of 1.2 μm

(5) n-type GaN waveguide layer 207 having a thickness of 0.1 μm

(6) In_{0.02}Ga_{0.98}N (thickness: 150 angstroms)/In_{0.15}Ga_{0.85}N (thickness: 50 angstroms) active layer 208 in the form of multiple quantum-well structure having a thickness of 0.033 μm

(7) p-type Al_{0.2}Ga_{0.8}N electron trapping layer 209 having a thickness of 0.02 μm

(8) p-type GaN waveguide layer 210 having a thickness of 0.1 μm

(9) p-type Al_{0.14}Ga_{0.86}N/GaN cladding layer 211 in the super lattice structure having a thickness of 0.6 μm

(10) p-type GaN contact layer 212 having a thickness of 0.05 μm

Subsequently, layers are etched till the p-type cladding layer 211 into a ridge geometry with a stripe width 2 μm. Further, layers are etched to expose the n-type contact layer 204 and form the surface on which the n-electrode is to be formed. Next, the protective layer 215 made of SiO₂ is formed on the side of the exposed laser device structure. And the p-electrode 214 made of Ni/Au is formed on the exposed p-type contact layer 212. The n-electrode 213 made of Ti/Al is formed on the surface of the n-type contact layer 204 which has been exposed. These electrodes are formed as a stripe in parallel with the direction of the ridge stripe.

After the n- and p-electrodes are formed, the etching is conducted to form a cleaved facet (a resonator plane) in such a manner that the resonator length is 650 μm, resulting in the laser device as shown in FIG. 5. For the laser device of Example 4, the threshold of 2.0 kA/cm² and the oscillation wavelength of 405 nm are achieved. Also, according to the laser device of Example 4, the occurrence of pits is suppressed and the device characteristic, particularly device lifetime, tends to be improved.

### EXAMPLE 5

Table 5 shows a laminated structure of the LED device of Example 5.

TABLE 5

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | GaN, thickness: 250 Å + Si doped |
| | In_{0.35}Ga_{0.65}N, thickness: 30 Å + |
| | (GaN, thickness: 250 Å/undoped |
| | In_{0.35}Ga_{0.65}N, thickness: 30 Å) × 5 + |
| | GaN, thickness: 250 Å |
| | Total thickness: 1930 Å |
| p-type multi-layered | (Mg doped Al_{0.2}Ga_{0.8}N, thickness: 40 |
| cladding layer 8 | Å/Mg doped In_{0.03}Ga_{0.97}N, thickness: |
| | 25 Å) × 5 + Mg doped Al_{0.03}Ga_{0.97}N, |
| | thickness: 40 Å |
| | Total thickness: 365 Å |
| Second contact layer 9 | Al_{0.05}Ga_{0.95}N, thickness: 2000 Å |
| p-type GaN contact | Mg doped GaN, thickness: 1200 Å |
| layer 10 | |

The LED device is fabricated in the same manner as in Example 2 except that the active layer is formed in the following way.

(Active Layer 7)

The first barrier layer made of undoped GaN is grown to the thickness of 250 angstroms. Subsequently, at 800° C., using TMG, TMI and ammonia, the first well layer made of In_{0.35}Ga_{0.65}N doped with Si to 1×10¹⁸/cm³ is grown to the thickness of 30 angstroms on the first barrier layer. Then, the second barrier layer made of undoped GaN is grown to the thickness of 250 angstroms on the first well layer. Further, at 800° C., using TMG, TMI and ammonia, the second well layer made of undoped In_{0.35}Ga_{0.65}N is grown to the thickness of 30 angstroms on the second barrier layer.

Thus, seven barrier layers and six well layers are laminated alternately in the order of the first barrier layer+the first well layer doped with Si+the second barrier layer+the undoped second well layer+the third barrier layer+the undoped third well layer . . . +the seventh barrier layer, resulting in the active layer 7 in the form of the multiple quantum-well structure having a total thickness of 1930 angstroms.

According to Example 5, in the active layer 7, the first well layer is a Si doped layer and the second to sixth layers are undoped layers and therefore, Vf of the resulting LED device can be reduced. Vf of the LED device of Example 5 was lower by 0.1 V than that of the LED device which was fabricated in the same manner as in Example 5 except that the active layer 7 was formed by laminating the first to seventh barrier layers made of undoped GaN and the first to sixth well layers made of undoped In_{0.35}Ga_{0.65}N alternately, instead of the first well layer being doped with Si.

The resulting LED device emitted the light of the wavelength of 505 nm at the forward current of 20 mA. Good results similar to those in Example 1 could be obtained.

### EXAMPLE 6

Table 6 shows a laminated structure of the LED device of Example 6.

TABLE 6

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å × 10 + GaN, |
| | thickness: 40 Å |
| | Total thickness: 640 Å |
| Active layer 7 | GaN, thickness: 250 Å + Si doped |
| | In_{0.4}Ga_{0.6}N, thickness: 30 Å + (GaN, |
| | thickness: 250 Å/undoped |
| | In_{0.35}Ga_{0.65}N, thickness: 30 Å) × 3 + |
| | GaN, thickness: 250 Å |
| | Total thickness: 1370 Å |
| p-type multi-layered | (Mg doped Al_{0.2}Ga_{0.8}N, thickness: 40 |
| cladding layer 8 | Å/Mg doped In_{0.03}Ga_{0.97}N, thickness: |
| | 25 Å) × 5 + Mg doped Al_{0.2}Ga_{0.8}N, |
| | thickness: 40 Å |
| | Total thickness: 365 Å |
| Second contact layer 9 | Al_{0.05}Ga_{0.95}N, thickness: 2000 Å |
| p-type GaN contact | Mg doped GaN, thickness: 1200 Å |
| layer 10 | |

The LED device is fabricated in the same manner as in Example 5 except that the active layer 7 is composed of the first to fifth barrier layers and the first to fourth well layers and the well layer is made of In_{0.4}Ga_{0.6}N. In Example 6, the active layer 7 is formed by laminating five barrier layers and four well layers alternately in the order of the first barrier layer made of undoped GaN (250 angstroms)+the first well layer made of Si doped In_{0.4}Ga_{0.6}N (30 angstroms)+the second barrier layer made of undoped GaN+the second well layer made of undoped In_{0.4}Ga_{0.6}N+the third barrier layer made of undoped GaN+the third well layer made of undoped In_{0.4}Ga_{0.6}N . . . +the fifth barrier layer made of undoped GaN. Thus, the active layer 7 in the form of a multiple quantum-well structure having a total thickness of 1370 angstroms is grown.

The resulting LED device emitted the light of the wavelength of 520 nm at the forward current of 20 mA. Good results similar to those in Example 1 could be obtained.

### EXAMPLE 7

Table 7 shows a laminated structure of the LED device of Example 7.

TABLE 7

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact | Si doped GaN, thickness: 10.165 μm |
| layer 4 | |
| n-side first multi- | GaN, thickness: 3000 Å/Si doped GaN, |
| layered film 5 | thickness: 300 Å/GaN, thickness: 50 Å |
| | Total thickness: 3350 Å |
| n-side second | (GaN, thickness: 40 Å/In_{0.13}Ga_{0.87}N; |
| multi-layered film | thickness: 20 Å) × 10 + GaN , |
| 6 | thickness: 40 Å |
| | Total thickness: 640 Å |
| Active layer 7 | (GaN, thickness: 250 Å/In_{0.3}Ga_{0.7}N, |
| | thickness: 30 Å) × 6 + GaN, |
| | thickness: 250 Å |
| | Total thickness: 1930 Å |
| p-type multi- | (Mg doped Al_{0.2}Ga_{0.8}N, thickness: 40 Å/ |
| layered cladding | Mg doped In_{0.03}Ga_{0.97}N, thickness: 25 Å) × |
| layer 8 | 5 + Mg doped Al_{0.2}Ga_{0.8}N, |
| | thickness: 40 Å |
| | Total thickness: 365 Å |
| Second contact | Al_{0.05}Ga_{0.95}N, thickness: 2800 Å |
| layer 9 | |
| p-type GaN contact | Mg doped GaN, thickness: 1200 Å |
| layer 10 | |

The LED device is fabricated in the same manner as in Example 2 except that the thickness of the n-type contact layer 4 is 10.165 μm and the thickness of the p-type lowly doped layer 9 is 2800 angstroms, the active layer 7 being formed by laminating alternately the barrier layer made of undoped GaN having a thickness of 250 angstroms and the well layer made of undoped In_{0.3}Ga_{0.7}N having a thickness of 30 angstroms. According to Example 7, the LED device having a high light emitting output could be fabricated.

### EXAMPLE 8

Table 8 shows a laminated structure of the LED device of Example 8.

TABLE 8

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 13.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/ |
| | In_{0.3}Ga_{0.7}N, thickness: 30 Å) × 6 + |
| | GaN, thickness: 250 Å |
| | Total thickness: 1930 Å |
| p-type multi-layered | (Mg doped Al_{0.2}Ga_{0.8}N, thickness: 40 |
| cladding layer 8 | Å/Mg doped In_{0.03}Ga_{0.97}N, thickness: |
| | 25 Å) × 5 + Mg doped Al_{0.2}Ga_{0.8}N, |
| | thickness: 40 Å |
| | Total thickness: 365 Å |
| Second contact layer 9 | Al_{0.05}Ga_{0.95}N, thickness: 2800 Å |
| p-type GaN contact | Mg doped GaN, thickness: 1200 Å |
| layer 10 | |

The LED device is fabricated in the same manner as in Example 7 except that the thickness of the n-type contact layer 4 is 13.165 μm. According to also Example 8, the LED device having a high light emitting output could be fabricated.

### EXAMPLE 9

Table 9 shows a laminated structure of the LED device of Example 9.

TABLE 9

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 10.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/In_{0.3}Ga_{0.7}N, |
| | thickness: 30 Å) × 10 + GaN, |
| | thickness: 250 Å |
| | Total thickness: 3050 Å |
| p-type multi-layered | (Mg doped Al_{0.2}Ga_{0.8}N, thickness: 40 |
| cladding layer 8 | Å/Mg doped In_{0.03}Ga_{0.97}N, thickness: |
| | 25 Å) × 5 + Mg doped Al_{0.2}Ga_{0.8}N, |
| | thickness: 40 Å |
| | Total thickness: 365 Å |
| Second contact layer 9 | Al_{0.05}Ga_{0.95}N, thickness: 2800 Å |
| p-type GaN contact | Mg doped GaN, thickness: 1200 Å |
| layer 10 | |

The LED device is fabricated in the same manner as in Example 7 except that the active layer 7 is formed in the following manner.

(Active Layer 7)

The barrier layer made of undoped GaN is grown to the thickness of 250 angstroms. Subsequently, at 800° C., using TMG, TMI and ammonia, the well layer made of undoped In_{0.3}Ga_{0.7}N is grown to the thickness of 30 angstroms. Thus, eleven barrier layers and ten well layers are laminated alternately in the order of the barrier layer+the well layer+the barrier layer+the well layer . . . +the barrier layer, resulting in the active layer 7 in the form of the multiple quantum-well structure having a total thickness of 3050 angstroms.

According to also Example 9, the LED device having a high light emitting output could be fabricated.

### EXAMPLE 10

Table 10 shows a laminated structure of the LED device of Example 10.

TABLE 10

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| n-type cladding layer | GaN, thickness: 1000 Å |
| Active layer 7 | (In_{0.3}Ga_{0.7}N, thickness: 30 Å/GaN, |
| | thickness: 250 Å) × 6 |
| | Total thickness: 1680 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 2 except that the n-type cladding layer is formed between the n-side second multi-layered film 6 and the active layer 7, the p-type cladding layer 8 of a single film is formed instead of the p-type cladding layer 8 of a multi-layered film, the active layer is in the form of a multi-layered structure as described later, and the second contact layer 9 is made of GaN. The n-type cladding layer, the active layer, the p-type cladding layer and the second contact layer 9 of the LED device according to the present invention will be described in the following part.

(n-Type Cladding Layer)

The n-type cladding layer is formed by growing the undoped GaN layer to the thickness of 1000 angstroms on the GaN layer which is the uppermost layer of the n-side second multi-layered film 6. The n-type cladding layer made of such GaN may be formed in the same process as that where the GaN layer, the uppermost layer of the n-side second multi-layered film 6 is formed, or may be formed in the different process where the conditions for forming a layer such as temperature are changed. The n-type cladding layer and the GaN layer which is the uppermost layer of the n-side second multi-layered film 6 are not distinguished clearly and one can also serve as the other. Where the above-mentioned n-type cladding layer is formed, it is considered that the static withstand voltage can be further enhanced and the output of the device can be improved.

(Active Layer 7)

The well layer made of undoped In_{0.3}Ga_{0.7}N is grown to the thickness of 30 angstroms on the n-type cladding layer using TMG, TMI and ammonia. Subsequently, the barrier layer made of undoped GaN is grown to the thickness of 250 angstroms. Thus, the process for forming an well layer and the process for forming a barrier layer are repeated alternately and successively. Six well layers and six barrier layers are laminated alternately in the order of the well layer+the barrier layer+the well layer . . . +the barrier layer, resulting in the active layer 7 in the form of the multiple quantum-well structure having a total thickness of 1680 angstroms.

(p-Type Cladding Layer 8 and the Second Contact Layer 9)

After the active layer is formed, the p-type cladding layer made of GaN doped with Mg to 5.0×10¹⁹/cm³ is grown to the thickness of 365 angstroms on the active layer 7. The second contact layer 9 made of undoped GaN is grown to the thickness of 2000 angstroms on the p-type cladding layer 8. According to also Example 10, the LED device having a high light emitting output could be fabricated.

### EXAMPLE 11

Table 11 shows a laminated structure of the LED device of Example 11.

TABLE 11

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| n-type cladding layer | GaN, thickness: 1000 Å |
| Active layer 7 | (In_{0.3}Ga_{0.7}N, thickness: 30 Å/GaN, |
| | thickness: 250 Å) × 5 |
| | Total thickness: 1400 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 10 except that the active layer 7 is formed by laminating five well layers made of undoped In_{0.3}Ga_{0.7}N and five barrier layers made of undoped GaN alternately in the order of the well layer+the barrier layer+the well layer . . . +the barrier layer, resulting in the multiple quantum-well structure having a total thickness of 1400 angstroms. According to also Example 11, the LED device having a high light emitting output could be fabricated.

### EXAMPLE 12

Table 12 shows a laminated structure of the LED device of Example 12.

TABLE 12

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness : 40 Å |
| | Total thickness: 640 Å |
| n-type cladding layer | GaN, thickness: 1000 Å |
| Active layer 7 | (In_{0.4}Ga_{0.6}N, thickness: 30 Å/GaN, |
| | thickness: 200 Å) × 4 |
| | Total thickness: 920 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 10 except that the active layer 7 is formed by laminating four well layers made of In_{0.4}Ga_{0.6}N having a thickness of 30 angstroms and four barrier layers made of undoped GaN having a thickness of 200 angstroms alternately in the order of the well layer+the barrier layer+the well layer . . . +the barrier layer, resulting in the multiple quantum-well structure having a total thickness of 920 angstroms. According to also Example 12, the LED device having a high light emitting output could be fabricated.

### EXAMPLE 13

Table 13 shows a laminated structure of the LED device of Example 13.

TABLE 13

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| n-type cladding layer | GaN, thickness: 1000 Å |
| Active layer 7 | Si doped In_{0.35}Ga_{0.65}N, thickness: 30 |
| | Å + (GaN, thickness: 250 Å/ |
| | In_{0.35}Ga_{0.65}N, thickness: 30 Å) × 5 + |
| | GaN, thickness: 250 Å |
| | Total thickness: 1680 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 10 except that the active layer 7 is formed in the following way.

(Active Layer 7)

At 800° C., the first well layer made of In_{0.35}Ga_{0.65}N doped with Si to 1×10¹⁸/cm³ is grown to the thickness of 30 angstroms on the n-type cladding layer using TMG, TMI and ammonia. Subsequently, the first barrier layer made of undoped GaN is grown to the thickness of 250 angstroms on the first well layer. Then, the second well layer made of undoped In_{0.35}Ga_{0.65}N is grown to the thickness of 30 angstroms on the first barrier layer at 800° C. using TMG, TMI and ammonia. Further, the second barrier layer made of undoped GaN is grown to the thickness of 250 angstroms on the first well layer.

As described above, the first well layer is a Si doped layer and the second to the sixth layers are undoped layers. Thus, six well layers and six barrier layers are laminated alternately in the order of the first well layer doped with Si+the first barrier layer+the undoped second well layer+the second barrier layer+the undoped third well layer+the third barrier layer . . . +the seventh barrier layer, resulting in the active layer 7 in the form of the multiple quantum-well structure having a total thickness of 1680 angstroms. According to also Example 13, the LED device having a high light emitting output could be fabricated.

### EXAMPLE 14

Table 14 shows a laminated structure of the LED device of Example 14.

TABLE 14

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| n-type cladding layer | GaN, thickness: 1000 Å |
| Active layer 7 | Si doped In_{0.4}Ga_{0.6}N, thickness: 30 |
| | Å + (GaN, thickness: 250 Å/ |
| | In_{0.4}Ga_{0.6}N, thickness: 30 Å) × 3 + |
| | GaN, thickness: 250 Å |
| | Total thickness: 1120 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 13 except that the active layer 7 is formed in the following way. The first well layer is made of In_{0.4}Ga_{0.6}N doped with Si to 1×10¹⁸/cm³ and the second to fifth well layers are made of undoped In_{0.4}Ga_{0.6}N. Four well layers and four barrier layers are laminated alternately in the order of the first well layer doped with Si+the first barrier layer+the undoped second well layer+the second barrier layer+the undoped third well layer+the third barrier layer . . . +the seventh barrier layer, resulting in the active layer 7 in the form of the multiple quantum-well structure having a total thickness of 1120 angstroms. According to also Example 14, the LED device having a high light emitting output could be fabricated.

### EXAMPLE 15

Table 15 shows a laminated structure of the LED device of Example 15.

TABLE 15

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/In_{0.3}Ga_{0.7}N, |
| | thickness: 30 Å) × 6 + GaN, |
| | thickness: 250 Å |
| | Total thickness: 1930 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 2 except that the p-type cladding layer 8 is in the form of a single film instead of the multi-layered film and the second contact layer is made of GaN, the active layer 7 being formed in the multi-layered film structure as described in the following part. The active layer, the p-type cladding layer 8 and the second contact layer 9 of the LED device according to the present invention will be described in the following part.

(Active Layer 7)

The barrier layer made of undoped GaN is grown to the thickness of 250 angstroms on the n-side second multi-layered film 6. Subsequently, at 800° C., the well layer made of undoped In_{0.3}Ga_{0.7}N is grown to the thickness of 40 angstroms. Thus, seven barrier layers and six well layers are laminated alternately in the order of the barrier layer+the well layer+the barrier layer+the well layer . . . +the barrier layer, resulting in the active layer 7 in the form of the multiple quantum-well structure having a total thickness of 1930 angstroms.

(p-Type Cladding Layer 8 and the Second Contact Layer 9)

After the active layer is formed, the p-type cladding layer made of GaN doped with Mg to 5.0×10¹⁹/cm³ is grown to the thickness of 365 angstroms on the active layer 7. The second contact layer 9 made of GaN is grown to the thickness of 2000 angstroms on the p-type cladding layer 8. According to also Example 15, the LED device having an excellent static withstand voltage characteristic could be fabricated.

### EXAMPLE 16

Table 16 shows a laminated structure of the LED device of Example 16.

TABLE 16

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/In_{0.3}Ga_{0.7}N, |
| | thickness: 30 Å) × 5 + GaN, |
| | thickness: 250 Å |
| | Total thickness: 1650 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 15 except that the active layer 7 in the form of the multiple quantum-well structure having a total thickness of 1650 angstroms is formed by laminating six barrier layers made of undoped GaN and five well layers made of undoped In_{0.3}Ga_{0.7}N alternately in the order of the barrier layer+the well layer . . . +the barrier layer. According to also Example 16, the LED device having a high light emitting output could be fabricated.

### EXAMPLE 17

Table 17 shows a laminated structure of the LED device of Example 17.

TABLE 17

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 200 Å/In_{0.4}Ga_{0.6}N, |
| | thickness: 30 Å) × 4 + GaN, |
| | thickness: 200 Å |
| | Total thickness: 1120 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 15 except that the active layer 7 in the form of the multiple quantum-well structure having a total thickness of 1120 angstroms is formed by laminating four well layers made of In_{0.4}Ga_{0.6}N having a thickness of 30 angstroms and five barrier layers made of undoped GaN having a thickness of 200 angstroms alternately in the order of the barrier layer+the well layer . . . +the well layer+the barrier layer. According to also Example 17, the LED device having a high light emitting output could be fabricated.

### EXAMPLE 18

Table 18 shows a laminated structure of the LED device of Example 18.

TABLE 18

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/ |
| layered film 5 | Si doped GaN, thickness: 300 Å/ |
| | GaN, thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | GaN, thickness: 250 Å + Si doped |
| | In_{0.35}Ga_{0.65}N, thickness: 30 Å + |
| | (GaN, thickness: 250 Å/ |
| | In_{0.35}Ga_{0.65}N, thickness: 30 Å) × 5 + |
| | GaN, thickness: 250 Å |
| | Total thickness: 1930 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 15 except that the active layer 7 is formed in the following way.

(Active Layer 7)

The first barrier layer made of undoped GaN is grown to the thickness of 250 angstroms on the n-side second multi-layered film 6. Subsequently, at 800° C., the first well layer made of In_{0.35}Ga_{0.65}N doped with Si to 1×10¹⁸/cm³ is grown to the thickness of 30 angstroms on the first barrier layer using TMG, TMI and ammonia. Then, the second barrier layer made of undoped GaN is grown to the thickness of 250 angstroms on the first well layer. Further, the second well layer made of undoped In_{0.35}Ga_{0.65}N is grown to the thickness of 30 angstroms on the first barrier layer at 800° C. using TMG, TMI and ammonia.

As described above, the first well layer is a Si doped layer and the second to the sixth layers are undoped layers. Thus, seven barrier layers and six well layers are laminated alternately in the order of the first barrier layer+the first well layer doped with Si+the second barrier layer+the undoped second well layer+the third barrier layer+the undoped third well layer . . . +the seventh barrier layer, resulting in the active layer 7 in the form of the multiple quantum-well structure having a total thickness of 1930 angstroms. According to also Example 18, the LED device having a high light emitting output could be fabricated.

### EXAMPLE 19

Table 19 shows a laminated structure of the LED device of Example 19.

TABLE 19

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | GaN, thickness: 250 Å + Si doped |
| | In_{0.4}Ga_{0.6}N, thickness: 30 Å + (GaN, |
| | thickness: 250 Å/In_{0.4}Ga_{0.6}N, |
| | thickness: 30 Å) × 3 + GaN, |
| | thickness: 250 Å |
| | Total thickness: 1370 Å |
| p-type cladding layer 8 | Mg doped GaN, thickness: 365 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 18 except that the active layer 7 is formed in the following way. The first well layer is made of In_{0.4}Ga_{0.6}N doped with Si to 1×10¹⁸/cm³ and the second to fifth well layers are made of undoped In_{0.4}Ga_{0.6}N. Five barrier layers and four well layers are laminated alternately in the order of the first barrier layer+the first well layer doped with Si+the second barrier layer+the undoped second well layer+the third barrier layer+the undoped third well layer . . . +the fifth barrier layer, resulting in the active layer 7 in the form of the multiple quantum-well structure having a total thickness of 1370 angstroms. According to also Example 19, the LED device having a high light emitting output could be fabricated.

### EXAMPLE 20

Table 20 shows a laminated structure of the LED device of Example 20.

TABLE 20

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/In_{0.3}Ga_{0.7}N, |
| | thickness: 30 Å) × 6 + GaN, |
| | thickness: 250 Å |
| | Total thickness: 1930 Å |
| p-type multi-layered | (Mg doped GaN, thickness: 40 Å/ |
| cladding layer 8 | In_{0.13}Ga_{0.87}N; thickness: 20 Å) × 10 + |
| | Mg doped GaN, thickness: 40 Å |
| | Total thickness: 640 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 2 except that the active layer 7, the p-type cladding layer 8 and the second contact layer 9 are formed in the following way. The active layer, the p-type cladding layer 8 and the second contact layer 9 of the LED device according to the present invention will be described in the following part.

(Active Layer 7)

The barrier layer made of undoped GaN is grown to the thickness of 250 angstroms on the n-side second multi-layered film 6. Subsequently, at 800° C., the well layer made of undoped In_{0.3}Ga_{0.7}N is grown to the thickness of 30 angstroms using TMG, TMI and ammonia. Thus, the processes for forming a well layer and a barrier layer are repeated alternately. Seven barrier layers and six well layers are laminated alternately in the order of the barrier layer+the well layer+the barrier layer+the well layer . . . +the barrier layer, resulting in the active layer 7 in the form of the multiple quantum-well structure having a total thickness of 1930 angstroms.

(p-Type Cladding Layer 8 and the Second Contact Layer 9)

After the active layer is formed, the nitride semiconductor layer made of GaN doped with Mg to 1×10¹⁹/cm³ is grown to the thickness of 40 angstroms. Subsequently, the nitride semiconductor layer made of In_{0.13}Ga_{0.87}N doped with Mg to 1×10¹⁹/cm³ is grown to the thickness of 20 angstroms. These processes are repeated. Thus, the Mg doped GaN layer and the Mg In_{0.13}Ga_{0.87}N doped layer are laminated alternately in this order, in 10 layers each. Finally, the Mg doped GaN layer is formed to the thickness of 40 angstroms, resulting in the p-type multi-layered cladding layer 8 in the form of a multi-layered film of a super lattice structure having a total thickness of 640 angstroms. Further, the second contact layer 9 made of GaN is grown to the thickness of 2000 angstroms on the p-type multi-layered cladding layer 8. According to also Example 20, the LED device having a high light emitting output could be fabricated.

### EXAMPLE 21

Table 21 shows a laminated structure of the LED device of Example 21.

TABLE 21

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 250 Å/In_{0.3}Ga_{0.7}N, |
| | thickness: 30 Å) × 5 + GaN, |
| | thickness: 250 Å |
| | Total thickness: 1650 Å |
| p-type multi-layered | (Mg doped GaN, thickness: 40 Å/ |
| cladding layer 8 | In_{0.13}Ga_{0.87}N; thickness: 20 Å) × 10 + |
| | Mg doped GaN, thickness: 40 Å |
| | Total thickness: 640 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 20 except that the active layer 7 is formed by laminating alternately six barrier layers made of undoped GaN and five well layers made of undoped In_{0.3}Ga_{0.7}N in the order of the barrier layer+the well layer . . . +the barrier layer, resulting in the active layer 7 in the form of the multiple quantum-well structure having a total thickness of 1650 angstroms. According to also Example 21, the LED device having a high light emitting output could be fabricated.

### EXAMPLE 22

Table 22 shows a laminated structure of the LED device of Example 22.

TABLE 22

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | (GaN, thickness: 200 Å/In_{0.4}Ga_{0.6}N, |
| | thickness: 30 Å) × 4 + GaN, |
| | thickness: 200 Å |
| | Total thickness: 1120 Å |
| p-type multi-layered | (Mg doped GaN, thickness: 40 Å/ |
| cladding layer 8 | In_{0.13}Ga_{0.87}N; thickness: 20 Å) × 10 + |
| | Mg doped GaN, thickness: 40 Å |
| | Total thickness: 640 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 18 except that the active layer 7 is formed by laminating alternately five barrier layers made of undoped GaN having a thickness of 200 angstroms and four well layers made of undoped In_{0.4}Ga_{0.6}N having a thickness of 30 angstroms in the order of the barrier layer+the well layer . . . +the barrier layer, resulting in the active layer 7 in the form of the multiple quantum-well structure having a total thickness of 1120 angstroms. According to also Example 22, the LED device having a high light emitting output could be fabricated.

### EXAMPLE 23

Table 23 shows a laminated structure of the LED device of Example 23.

TABLE 23

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | GaN, thickness: 250 Å + Si doped |
| | In_{0.35}Ga_{0.65}N, thickness: 30 Å + |
| | (GaN, thickness: 250 Å/undoped |
| | In_{0.35}Ga_{0.65}N, thickness: 30 Å) × 5 + |
| | GaN, thickness: 250 Å |
| | Total thickness: 1930 Å |
| p-type multi-layered | (Mg doped GaN, thickness: 40 Å/ |
| cladding layer 8 | Mg doped In_{0.13}Ga_{0.87}N, thickness: 20 |
| | Å) × 10 + Mg doped GaN, thickness: |
| | 40 Å |
| | Total thickness: 640 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 20 except that the active layer 7 is formed in the following way.

(Active Layer 7)

The first barrier layer made of undoped GaN is grown to the thickness of 250 angstroms on the n-side second multi-layered film 6. Subsequently, at 800° C., the first well layer made of In_{0.35}Ga_{0.65}N doped with Si to 1×10¹⁸/cm³ is grown to the thickness of 30 angstroms using TMG, TMI and ammonia. Then, the second barrier layer made of undoped GaN is grown to the thickness of 250 angstroms. Further, the second well layer made of undoped In_{0.35}Ga_{0.65}N is grown to the thickness of 30 angstroms on the first well layer at 800° C. using TMG, TMI and ammonia.

As described above, the first well layer is a Si doped layer and the second to the sixth layers are undoped layers. Thus, seven barrier layers and six well layers are laminated alternately in the order of the first barrier layer+the first well layer doped with Si+the second barrier layer+the undoped second well layer+the third barrier layer+the undoped third well layer . . . +the seventh barrier layer, resulting in the active layer 7 in the form of the multiple quantum-well structure having a total thickness of 1930 angstroms. According to also Example 23, the LED device having a high light emitting output could be fabricated.

### EXAMPLE 24

Table 24 shows a laminated structure of the LED device of Example 24.

TABLE 24

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.13}Ga_{0.87}N; |
| layered film 6 | thickness: 20 Å) × 10 + GaN, |
| | thickness: 40 Å |
| | Total thickness: 640 Å |
| Active layer 7 | GaN, thickness: 250 Å + Si doped |
| | In_{0.4}Ga_{0.6}N, thickness: 30 Å + (GaN, |
| | thickness: 250 Å/In_{0.4}Ga_{0.6}N, |
| | thickness: 30 Å) × 3 + GaN, |
| | thickness: 250 Å |
| | Total thickness: 1370 Å |
| p-type multi-layered | (Mg doped GaN, thickness: 40 Å/ |
| cladding layer 8 | Mg doped In_{0.13}Ga_{0.87}N, thickness: 20 |
| | Å) × 10 + Mg doped GaN, thickness: |
| | 40 Å |
| | Total thickness: 640 Å |
| Second contact layer 9 | GaN, thickness: 2000 Å |
| p-type GaN contact | Mg doped GaN, thickness: 1200 Å |
| layer 10 | |

The LED device is fabricated in the same manner as in Example 23 except that the active layer 7 is formed in the following way. The first well layer is made of In_{0.4}Ga_{0.6}N doped with Si to 1×10¹⁸/cm³ and the second to fifth well layers are made of undoped In_{0.4}Ga_{0.6}N. Five barrier layers and four well layers are laminated alternately in the order of the first barrier layer+the first well layer doped with Si+the second barrier layer+the undoped second well layer+the third barrier layer+the undoped third well layer . . . +the fifth barrier layer, resulting in the active layer 7 in the form of the multiple quantum-well structure having a total thickness of 1370 angstroms. According to also Example 24, the LED device having a high light emitting output could be fabricated.

### EXAMPLES 25 TO 29

Tables 25 to 29 show laminated structures of the LED devices of Example 25 to 29, respectively.

TABLE 25

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/ |
| layered film 5 | Si doped GaN, thickness: 300 Å/ |
| | GaN, thickness: 50 Å |
| | Total thickness: 3350 Å |
| n-side second multi- | (GaN, thickness: 40 Å/In_{0.09}Ga_{0.91}N; |
| layered film 6 | thickness: 20 Å) × 5 + GaN, |
| | thickness: 40 Å |
| | Total thickness: 340 Å |
| Active layer 7 | (GaN, thickness: 250 Å/In_{0.3}Ga_{0.7}N, |
| | thickness: 30 Å) × 6 + GaN, |
| | thickness: 250 Å |
| | Total thickness: 1930 Å |
| p-type multi-layered | (GaN, thickness: 40 Å/In_{0.09}Ga_{0.91}N, |
| cladding layer 8 | thickness: 20 Å) × 5 × GaN, |
| | thickness: 40 Å |
| | Total thickness: 340 Å |
| Second contact layer 9 | GaN, thickness: 2000 Å |
| p-type GaN contact | Mg doped GaN, thickness: 1200 Å |
| layer 10 | |

TABLE 26

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.09}Ga_{0.91}N; |
| layered film 6 | thickness: 20 Å) × 5 + GaN, |
| | thickness: 40 Å |
| | Total thickness: 340 Å |
| Active layer 7 | (GaN, thickness: 250 Å/In_{0.3}Ga_{0.7}N, |
| | thickness: 30 Å) × 5 + GaN, |
| | thickness: 250 Å |
| | Total thickness: 1650 Å |
| p-type multi-layered | (GaN, thickness: 40 Å/In_{0.09}Ga_{0.91}N, |
| cladding layer 8 | thickness: 20 Å) × 5 + GaN, |
| | thickness: 40 Å |
| | Total thickness: 340 Å |
| Second contact layer 9 | GaN, thickness: 2000 Å |
| p-type GaN contact | Mg doped GaN, thickness: 1200 Å |
| layer 10 | |

TABLE 27

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.09}Ga_{0.91}N; |
| layered film 6 | thickness: 20 Å) × 5 + GaN, |
| | thickness: 40 Å |
| | Total thickness: 340 Å |
| Active layer 7 | (GaN, thickness: 200 Å/In_{0.4}Ga_{0.6}N, |
| | thickness: 30 Å) × 4 + GaN, |
| | thickness: 200 Å |
| | Total thickness: 1120 Å |
| p-type cladding layer 8 | (GaN, thickness: 40 Å/In_{0.09}Ga_{0.91}N, |
| | thickness: 20 Å) × 5 + GaN, |
| | thickness: 40 Å |
| | Total thickness: 340 Å |
| Second contact layer 9 | GaN, thickness: 2000 Å |
| p-type GaN contact | Mg doped GaN, thickness: 1200 Å |
| layer 10 | |

TABLE 28

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.09}Ga_{0.91}N; |
| layered film 6 | thickness: 20 Å) × 5 + GaN, |
| | thickness: 40 Å |
| | Total thickness: 340 Å |
| Active layer 7 | GaN, thickness: 250 Å + Si doped |
| | In_{0.35}Ga_{0.65}N, thickness: 30 Å + |
| | (GaN, thickness: 250 Å/undoped |
| | In_{0.35}Ga_{0.65}N, thickness: 30 Å) × 5 + |
| | GaN, thickness: 250 Å |
| | Total thickness: 1930 Å |
| p-type multi-layered | (GaN, thickness: 40 Å/In_{0.09}Ga_{0.91}N, |
| cladding layer 8 | thickness: 20 Å) × 5 + GaN, |
| | thickness: 40 Å |
| | Total thickness: 340 Å |
| Second contact layer 9 | GaN, thickness: 2000 Å |
| p-type GaN contact | Mg doped GaN, thickness: 1200 Å |
| layer 10 | |

TABLE 29

| layer | composition |
|---|---|
| Buffer layer 2 | Al_{0.25}Ga_{0.75}N, thickness: 100 Å |
| Undoped GaN layer 3 | GaN, thickness: 1.5 μm |
| n-type contact layer 4 | Si doped GaN, thickness: 4.165 μm |
| n-side first multi- | GaN, thickness: 3000 Å/Si doped |
| layered film 5 | GaN, thickness: 300 Å/GaN, |
| | thickness: 50 Å |
| | Total thickness: 3350 Å |
| n-side second multi- | (GaN, thickness: 40 Å/In_{0.09}Ga_{0.91}N; |
| layered film 6 | thickness: 20 Å) × 5 + GaN, |
| | thickness: 40 Å |
| | Total thickness: 340 Å |
| Active layer 7 | GaN, thickness: 250 Å + Si doped |
| | In_{0.4}Ga_{0.6}N, thickness: 30 Å + (GaN, |
| | thickness: 250 Å/undoped |
| | In_{0.4}Ga_{0.6}N, thickness: 30 Å) × 3 + |
| | GaN, thickness: 250 Å |
| | Total thickness: 1370 Å |
| p-type multi-layered | (GaN, thickness: 40 Å/In_{0.09}Ga_{0.91}N, |
| cladding layer 8 | thickness: 20 Å) × 5 + GaN, |
| | thickness: 40 Å |
| | Total thickness: 340 Å |
| Second contact layer 9 | GaN, thickness: 2000 Å |
| p-type GaN contact | Mg doped GaN, thickness: 1200 Å |
| layer 10 | |

The LED devices of Examples 25 to 29 are fabricated in the same manner as in Examples 20 to 24, respectively, except that the n-side second multi-layered film 6 and the p-type cladding layer 8 are formed in the following way. The n-side second multi-layered film 6 and the p-type cladding layer 8 of the LED device according to the present invention will be described in the following part.

(n-Side Second Multi-Layered Film 6 and p-Type Multi-Layered Cladding Layer 8)

A second nitride semiconductor layer made of undoped GaN is grown to the thickness of 40 angstroms on the n-side first multi-layered film 5. Next, at 800° C., using TMG, TMI and ammonia, a first nitride semiconductor layer made of undoped In_{0.09}Ga_{0.91}N si grown to the thickness of 20 angstroms. These processes are repeated. The second nitride semiconductor layers and the first nitride semiconductors are laminated alternately in this order, in five layers each and finally, the second nitride semiconductor layer made of GaN is grown to the thickness of 40 angstroms. Thus, the n-side second multi-layered film 6 in the form of a super lattice structure having a total thickness of 340 angstroms is formed.

The multi-layered film similar to the n-side second multi-layered film 6 is formed on the active layer 7, resulting in the p-type multi-layered cladding layer 8. According to also Examples 25 to 29, the LED devices having a high light emitting output could be fabricated.

### COMPARATIVE EXAMPLE 1

The LED device of Comparative Example 1 is fabricated in the same manner as in Example 1 except that the buffer layer 2 is made of undoped GaN.

### COMPARATIVE EXAMPLE 2

The LED device of Comparative Example 2 is fabricated in the same manner as in Example 2 except that the buffer layer 2 is made of undoped GaN.

As described above, according to the present invention, there are provided an n-type semiconductor laminate in which the nitride semiconductor layers can be formed with a good crystallinity and a semiconductor device using the same.

Although the present invention has been fully described by way of examples with reference to the accompanying drawings, it is to be noted here that various changes and modifications will be apparent to those skills in the art. Therefore, unless such changes and modifications otherwise depart from the spirit and scope of the present invention, they should be constructed as being included therein.

1. An N-type nitride semiconductor laminate comprising:
a substrate;
a buffer layer made of AlₐGa₁₋ₐN (0.05≦a≦0.8) which is formed on a surface of the substrate; and
an n-side nitride semiconductor layer which is formed on the buffer layer.

2. An N-type nitride semiconductor laminate according to claim 1,
wherein the buffer layer is made of AlₐGa₁₋ₐN (0.1≦a≦0.5).

3. An N-type nitride semiconductor laminate according to claim 2, wherein the n-side nitride semiconductor layer comprises an undoped Al_{b}Ga_{1-b}N (0≦b<1) which is formed on the buffer layer and an n-type contact layer containing an n-type impurity which is formed on the undoped Al_{b}Ga_{1-b}N layer.

4. An N-type nitride semiconductor laminate according to claim 3,
wherein the n-side first multi-layered film is formed on the n-type contact layer and comprises an undoped bottom layer.

5. An N-type nitride semiconductor laminate according to claim 4,
wherein the n-side first multi-layered film further comprises a middle layer doped with an n-type impurity which is formed on the undoped bottom layer.

6. An N-type nitride semiconductor laminate according to claim 5,
wherein the n-side first multi-layered film further comprises an undoped top layer which is formed on the middle layer doped with an n-type impurity.

7. An N-type nitride semiconductor laminate according to claim 5,
wherein the n-type contact layer has a thickness larger than that of the middle layer doped with an n-type impurity which is included within the n-side first multi-layered film.

8. An N-type nitride semiconductor laminate according to claim 6,
wherein the undoped top layer has a thickness smaller than that of the undoped bottom layer in the n-side first multi-layered film.

9. An N-type nitride semiconductor laminate according to claim 3, wherein the undoped Al_{b}Ga_{1-b}N layer is formed of Al_{b}Ga_{1-b}N (0.001≦b≦0.1).

10. An N-type nitride semiconductor laminate according to claim 3, wherein the n-type contact layer has a thickness in a range of 6 to 20 μm.

11. A semiconductor device comprising an n-type nitride semiconductor laminate formed on a buffer layer on a substrate, the n-type nitride semiconductor laminate being formed by laminating n-side nitride semiconductor layers and p-side nitride semiconductor layers with an active layer interposed,
wherein the buffer layer is made of AlₐGa₁₋ₐN (0.05≦a≦0.8).

12. A semiconductor device according to claim 11, wherein the buffer layer is made of AlₐGa₁₋ₐN (0.1≦a≦0.5).

13. A semiconductor device according to claim 12, wherein the n-side nitride semiconductor layer comprises an undoped Al_{b}Ga_{1-b}N (0≦b<1) which is formed on the buffer layer and an n-type contact layer containing an n-type impurity which is formed on the undoped Al_{b}Ga_{1-b}N layer.

14. A semiconductor device according to claim 13, wherein an n-side first multi-layered film is formed on the n-type contact layer and comprises an undoped bottom layer.

15. A semiconductor device according to claim 14,
wherein the n-side first multi-layered film further comprises a middle layer doped with an n-type impurity which is formed on the undoped bottom layer.

16. A semiconductor device according to claim 15,
wherein the n-side first multi-layered film further comprises an undoped top layer which is formed on the middle layer doped with an n-type impurity.

17. A semiconductor device according to claim 15,
wherein the n-type contact layer has a thickness larger than that of the middle layer doped with an n-type impurity which is included within the n-side first multi-layered film.

18. A semiconductor device according to claim 16,
wherein the undoped top layer has a thickness smaller than that of the undoped bottom layer in the n-side first multi-layered film.

19. A semiconductor device according to claim 13, wherein the undoped Al_{b}Ga_{1-b}N layer is formed of Al_{b}Ga_{1-b}N (0.001≦b≦0.1).

20. A semiconductor device according to claim 13, wherein the n-type contact layer has a thickness in a range of 6 to 20 μm.

21. A semiconductor device according to claim 14, wherein the active layer is formed of In_{c}Ga_{1-c}N (0<c<1) and the n-side nitride semiconductor layer further comprises an n-side second multi-layered film formed on the n-side first multi-layered film by laminating a first nitride semiconductor layer formed of In_{d}Ga_{1-d}N (0<d<1, d<c) and a second nitride semiconductor layer formed of InₑGa₁₋ₑN (0≦e<1, e<d).
